(19) United States
(12) Patent Application Publication
(10) Pub. No.: US 2017/0184665 A1
(43) Pub. Date: Jun. 29, 2017

(54) DYNAMICALLY CONFIGURABLE SHARED SCAN CLOCK CHANNEL ARCHITECTURE

(71) Applicant: QUALCOMM Incorporated, San Diego, CA (US)

(72) Inventors: Rajesh Tiwari, Bangalore (IN); Venkata Raghava Sesha Sai Aduru, Bangalore (IN); Manish Kumar Pillai, Bangalore (IN); Nishi Bhushan Singh, Bangalore (IN)

(21) Appl. No.: 14/981,716

(22) Filed: Dec. 28, 2015

(51) Int. Cl. G01R 31/3177; G01R 31/317

(52) U.S. Cl. CPC G01R 31/3177; G01R 31/31727

(57) ABSTRACT

A method and apparatus for testing an electronic device with multiple cores is provided. The method begins when at least one scan is input for scan configuring. A signal having a predetermined number of bits is then input to a decoder. The decoder then outputs at least one assigned test channel based on the output of the decoder. A test control block then switches at least one selected scan in channel to a test control block. A hard macro scan out of channels is then input to a channel maximization device which allocates or re-allocates the channels for testing. Testing proceeds once the channels are allocated. An apparatus includes a programmable scan configuration block for adjusting the number of scan out channels to maximize testing resources and a predetermined bit register in communication with the programmable scan configuration block.

### BACKGROUND

Field

The present disclosure relates generally to wireless communication system. More specifically the present disclosure related to methods and apparatus for an architecture that provides a dynamically configurable shared scan clock channel that enables maximum use of automated test equipment (ATE) resources during scan chain testing.

Background

Wireless communication devices have become smaller and more powerful as well as more capable. Increasingly users rely on wireless communication devices for mobile phone use as well as email and Internet access. At the same time, devices have become smaller in size. Devices such as cellular telephones, personal digital assistants (PDAs), laptop computers, and other similar devices provide reliable service with expanded coverage areas. Such devices may be referred to as mobile stations, stations, access terminals, user terminals, subscriber units, user equipment, and similar terms.

These wireless communication devices typically use a system-on-chip (SoC) to provide many of the functions of the device. A SoC is an integrated circuit that combines all components of a computer or other electronic system on a single chip. The SoC device may contain digital, analog, mixed-signal, and radio frequency (RF) functions on a single substrate. SoCs are used widely due to their low power consumption.

A SoC may consist of a microcontroller or digital signal processor (DSP) core, memory blocks including a selection of ROM, RAM, EEPROM, and flash memory, as well as timing sources. The timing sources may include oscillators and phase-locked loops (PLL). Peripherals, including counter-timers, real-time timers, and power-on reset generators may also be incorporated. A wide variety of external and internal interfaces including analog-to-digital (ADC), digital-to-analog converters (DAC), voltage regulators and power management circuits are also typically included in a SoC. The desired performance of the end device may result in different mixes of the above functions to be included in the SoC. The SoC also includes a bus system for connecting the various functional blocks.

Testing a SoC may be complex and time consuming. During testing of an SoC a fixed number of clock, scan in, and scan out channels are typically used for scan testing with ATE. All of the hard macros used in this testing are designed for the same number of scan in and scan out operations. Since 90% of the hard macros require only a few of the assigned clock channels, under-utilization of the ATE resources occurs, as many channels are not used. Automated test pattern generation (ATPG) may contribute up to 50% of the total test time.

There is a need in the art for a method and apparatus for reducing ATPG test time, test data volume, and improving use of clock, scan in, and scan out channels.

### SUMMARY

Embodiments described herein provide a method for testing an electronic device with multiple cores. The method begins when at least one scan is input for scan configuring. A signal having a predetermined number of bits is then input to a decoder. The decoder then outputs at least one assigned test channel based on the output of the decoder. A test control block then switches at least one selected scan in channel to a test control block. A hard macro scan out of channels is then input to a channel maximization device which allocates or re-allocates the channels for testing. Testing proceeds once the channels are allocated.

An additional embodiment provides an apparatus for testing an electronic device having multiple channels. The device includes a programmable scan configuration block for adjusting the number of scan out channels to maximize testing resources and a predetermined bit register in communication with the programmable scan configuration block.

A further embodiment provides an apparatus for testing a device with multiple cores. The apparatus includes means for inputting at least one scan for scan configuring; means for inputting a signal having a predetermined number of bits to a decoder; means for outputting at least one assigned test channel based on the output of the decoder; means for switching at least one selected scan in channel to a test control block; means for inputting hard macro scan out channels to a channel maximization device; and means for testing the electronic device.

### BRIEF DESCRIPTION OF THE DRAWINGS

FIG. 1 is a block diagram of a SoC, in accordance with embodiments disclosed herein.

FIG. 2 is a block diagram of a dynamically configurable shared scan clock channel architecture, in accordance with embodiments disclosed herein.

FIG. 3 depicts the differences between current scan clock channel architecture and a shared scan clock channel architecture, in accordance with embodiments disclosed herein.

FIG. 4 is a block diagram of the programmable scan configuration block, in accordance with embodiments disclosed herein.

FIG. 5 is a schematic diagram of the Smart XOR used in the programmable scan configuration block, in accordance with embodiments disclosed herein.

FIG. 6 depicts the effect of scan chain length on test time, in accordance with embodiments disclosed herein.

FIG. 7 illustrates the differences between serial and parallel testing for smaller cores, in accordance with embodiments disclosed herein.

FIG. 8 is a flowchart of a method of testing an electronic device using a dynamically configurable shared scan clock architecture, in accordance with embodiments described herein.

### DETAILED DESCRIPTION

Various aspects are now described with reference to the drawings. In the following description, for purposes of explanation, numerous specific details are set forth in order to provide a thorough understanding of one or more aspects. It may be evident, however, that such aspect(s) may be practiced without these specific details.

As used in this application, the terms “component,” “module,” “system” and the like are intended to include a computer-related entity, such as, but not limited to hardware, firmware, a combination of hardware and software, software, or software in execution. For example, a component may be, but is not limited to being, a process running on a processor, a processor, an object, an executable, a thread of execution, a program and/or a computer. By way of illustration, both an application running on a computing device and the computing device can be a component. One or more components can reside within a process and/or thread of execution and a component may be localized on one computer and/or distributed between two or more computers. In addition, these components can execute from various computer readable media having various data structures stored thereon. The components may communicate by way of local and/or remote processes such as in accordance with a signal having one or more data packets, such as data from one component interacting with another component in a local system, distributed system, and/or across a network such as the Internet with other systems by way of the signal.

As used herein, the term “determining” encompasses a wide variety of actions and therefore, “determining” can include calculating, computing, processing, deriving, investigating, looking up (e.g., looking up in a table, a database or another data structure), ascertaining and the like. Also, “determining” can include resolving, selecting choosing, establishing, and the like.

The phrase “based on” does not mean “based only on,” unless expressly specified otherwise. In other words, the phrase “based on” describes both “based only on” and “based at least on.”

Moreover, the term “or” is intended to man an inclusive “or” rather than an exclusive “or.” That is, unless specified otherwise, or clear from the context, the phrase “X employs A or B” is intended to mean any of the natural inclusive permutations. That is, the phrase “X employs A or B” is satisfied by any of the following instances: X employs A; X employs B; or X employs both A and B. In addition, the articles “a” and “an” as used in this application and the appended claims should generally be construed to mean “one or more” unless specified otherwise or clear from the context to be directed to a singular form.

The various illustrative logical blocks, modules, and circuits described in connection with the present disclosure may be implemented or performed with a general purpose processor, a digital signal processor (DSP), an application specific integrated circuit (ASIC), a field programmable gate array (FPGA), or other programmable logic device, discrete gate or transistor logic, discrete hardware components or any combination thereof designed to perform the functions described herein. A general purpose processor may be a microprocessor, but in the alternative, the processor may be any commercially available processor, controller, microcontroller, or state machine. A processor may also be implemented as a combination of computing devices, e.g., a combination of a DSP and a microprocessor, a plurality of microprocessors, one or more microprocessors in conjunction with a DSP core or any other such configuration.

The steps of a method or algorithm described in connection with the present disclosure may be embodied directly in hardware, in a software module executed by a processor or in a combination of the two. A software module may reside in any form of storage medium that is known in the art. Some examples of storage media that may be used include RAM memory, flash memory, ROM memory, EPROM memory, EEPROM memory, registers, a hard disk, a removable disk, a CD-ROM, and so forth. A software module may comprise a single instruction, or many instructions, and may be distributed over several different code segments, among different programs and across multiple storage media. A storage medium may be coupled to a processor such that the processor can read information from, and write information to, the storage medium. In the alternative, the storage medium may be integral to the processor.

The methods disclosed herein comprise one or more steps or actions for achieving the described method. The method steps and/or actions may be interchanged with one another without departing from the scope of the claims. In other words, unless a specific order of steps or actions is specified, the order and/or use of specific steps and/or actions may be modified without departing from the scope of the claims.

The functions described may be implemented in hardware, software, firmware, or any combination thereof. If implemented in software, the functions may be stored as one or more instructions on a computer-readable medium. A computer-readable medium may be any available medium that can be accessed by a computer. By way of example, and not limitation, a computer-readable medium may comprise RAM, ROM, EEPROM, CD-ROM or other optical disk storage, magnetic disk storage, or other magnetic storage devices, or any other medium that can be used to carry or store desired program code in the form of instructions or data structures and that can be accessed by a computer. Disk and disc, as used herein, includes compact disk (CD), laser disk, optical disc, digital versatile disk (DVD), floppy disk, and Blu-ray® disc where disks usually reproduce data magnetically, while discs reproduce data optically with lasers.

Software or instructions may also be transmitted over a transmission medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of transmission medium.

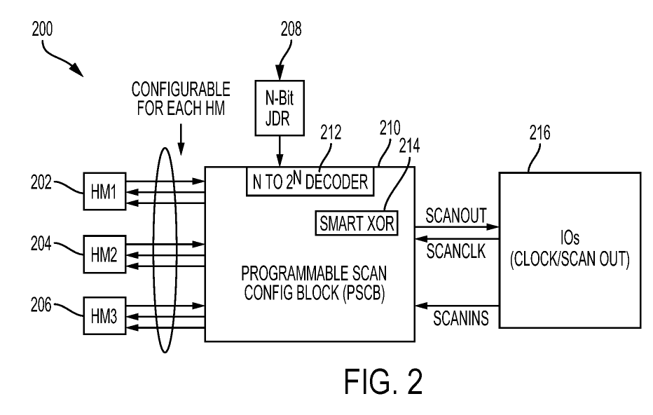

Further, it should be appreciated that modules and/or other appropriate means for performing the methods and techniques described herein, such as those illustrated by FIGS. 2-8, can be downloaded and/or otherwise obtained by a mobile device and/or base station as applicable. For example, such a device can be coupled to a server to facilitate the transfer of means for performing the methods described herein. Alternatively, various methods described herein can be provided via a storage means (e.g., random access memory (RAM), read only memory (ROM), a physical storage medium such as a compact disc (CD) or floppy disk, etc.), such that a mobile device and/or base station can obtain the various methods upon coupling or providing the storage means to the device. Moreover, any other suitable technique for providing the methods and techniques described herein to a device can be utilized.

Embodiments described herein relate to an architecture for test input and test output configuration logic using a programmable scan configuration block (PSCB). The PSCB controls clock channel direction in testing mode. The embodiments provide for re-using unused ATE test channels and resources when hard macros are being tested. This reduces test time, possibly by 30%-40%, and also reduces test volume without sacrificing result quality. The PSCB reuses unused clock channels to design the hard macro scans in accordance with test requirements. In operation, the PSCB is programmed with the desired number of channels needed on scan in and on scan out. The PSCB uses a smart XOR, which operates on the output logic. On the input side, the scan in inputs are fanned out. On the output side the smart XOR logic allows the highest number of scan out operations. The XOR ties unused input signals to 0. The PSCB is a reconfigurable block that re-purposes the unused clock channels, thus allowing better compression testing while reducing test time. The PSCB permits design of hard macro scans in accordance with the particular design requirements of the hard macros contained in the SoC. Further embodiments provides for parallel core testing.

Testing may also involve testing hard macros (HM). A hard macro is a custom block that is used in digital logic. A hard macro may be fixed in size. Hard macros may be stored in memory, which carries a dedicated single function. In many cases, hard macros for specific custom functions may be included within a SoC and these must be tested during memory built-in testing (MBIST) and other device functionality testing. Embodiments described herein reuse unused tester channels or other testing resources during HM testing. This allows for significant reduction in reducing the time needed to generate automated test patterns created by automated test pattern generators.

A SoC is an integrated circuit that combines all components of a computer or other electronic system on a single chip. It may contain digital, analog, mixed-signal, and radio frequency (RF) functions. A SoC may consist of: a microcontroller or digital signal processor (DSP) core; memory blocks, including a selection of read-only memory (ROM), random access memory (RAM), electrically erasable programmable read-only memory (a type of non-volatile memory), and flash memory; timing sources including oscillators and phase-locked loops (PLL); peripherals including counter-timers, real-time timers, and power-on or reset generators; external interfaces; analog interfaces including analog to digital converters (ADC), digital to analog converters (DAC); voltage regulators; and power management circuits. A bus connects these blocks within the SoC.

Direct memory access (DMA) controllers route data directly between external interfaces and memory, bypassing the processor core, thus increasing data throughput. DMA controllers are used because they allow certain hardware systems to access the main system memory (RAM) independently of the CPU and as a result improve data processing speed.

Many SoCs incorporate an Acorn Risc Machine (ARM) proprietary process into their architecture. A reduced instruction set computing (RISC) device may be used as a building block within a larger and more complex device, such as a SoC. The ARM processors may be configured for various environments. A RISC based design means that ARM processors require significantly fewer transistors than a complex instruction set computing (CISC) device, such as those found in most personal computers. This approach results in lower cost, less heat production, and less power consumed. As a result, ARM processors are used extensively in portable devices such as wireless devices and tablet, as well as in embedded systems. ARM processors use a simpler design with more efficient multi-core central processing units (CPU).

An ARM processor core may support a 32-bit address space and use 32-bit arithmetic. Instructions for ARM cores often use 32-bit wide fixed length instructions, however, some versions support a variable length instruction set that uses 32-bit and 16-bit wide instruction sets for improved code density. In many cases, a SoC will use the standard ARM processor core and will use a 32-bit address space and 32-bit arithmetic. However, some SoCs allow for a reduction in memory size by blowing a fuse. This process of reducing memory size by blowing a fuse is known as de-featuring. As an example, in one SoC core, the cache may be reduced from 1 MB to 512 KB during the manufacturing process. This allows a simple memory size reduction without the time and expense of a redesign.

Testing the SoCs is an important part of the manufacturing process. Automated test equipment (ATE) is used to perform tests on a device, known as the device under test (DUT) using automation to quickly perform measurements and evaluate test results. An ATE may be a simple computer-controlled digital multimeter, or may be a more complex system with many test instruments capable of testing and diagnosing faults in SoCs. ATE systems are designed to reduce the amount of test time needed to verify that a particular electronic device functions correctly, or to quickly find the faults before the device is installed in an end product, such as a wireless device. An ATE system may consist of a master controller (often a computer) that synchronizes one or more capture instruments.

Register transfer level (RTL) is a design abstraction which models a synchronous digital circuit in terms of the flow of digital signals between hardware registers and logical operations performed on those signals. RTL abstraction may be used in hardware design description languages, such as Verilog, and VHDL to create high-level representations of a circuit, from which lower-level representations and ultimately actual wiring can be derived. RTL focuses on describing the flow of signals between registers.

RTL is used in the logic design phase of the SoC design cycle. An RTL description may be converted to a gate-level description of the circuit by a logic synthesis tool. The synthesis results are then used by placement and routing tools to create a physical layout. Logic simulation tools may use a design's RTL description to verify its correctness. When the RTL logic insertion must be re-done during a redesign, the MBIST logic testing flow must also be redesigned, significantly increasing costs. The configuration of the MBIST logic should be in accordance with the memory configuration for the test to be successful.

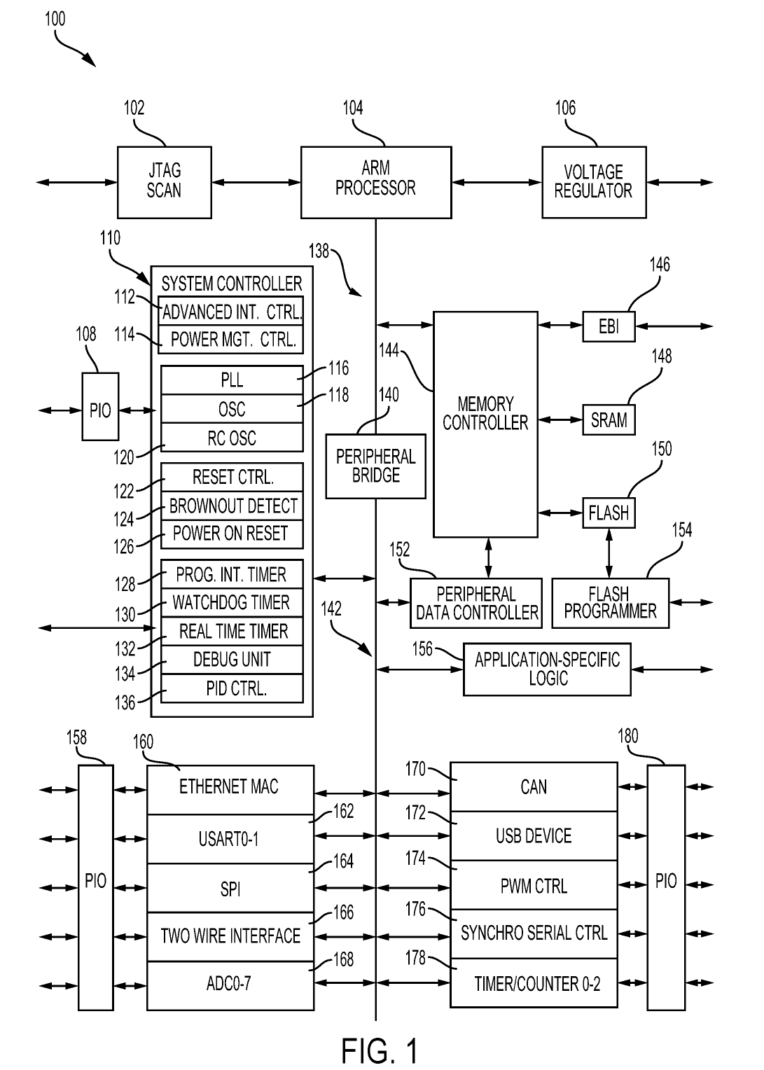

FIG. 1 illustrates a SoC, 100. The assembly 100 includes joint test action group (JTAG) scan device 102, which receives input signals for scanning. These signals are scanned before being sent to the ARM processor 104. The ARM processor 104 may also send input to JTAG scan device 102, which in turn may provide output. The ARM processor also interfaces with voltage regulator 106. The SoC 100 may also incorporate a first peripheral input/output interface (PIO) 108. This PIO 108 interfaces with a system controller 110. System controller 110 may incorporate an advanced interface controller 112, a power management controller 114, a phase locked loop (PLL) 116, an oscillator 118, a resistor-capacitor (RC) oscillator 120, a reset controller 122, a brownout detector 124, a power on reset device 126, a program interrupt timer 128, a watchdog timer 130, a real time timer 132, a debug unit 134, and a proportional/integral/derivative (PID) controller 136. All of the devices under the control of system controller 110 interface through the PIO.

The ARM processor 104 interfaces with peripheral bridge 140, which also provides input and output interface with the system controller 110. The peripheral bridge communicates with multiple components using an application peripheral bus (APB) 142. An internal bus 138 operates in conjunction with the peripheral bridge 140 to communicate with additional devices within the SoC 100. The internal bus 138 may be an application specific bus (ASP) or an application handling bus (AHB). Memory controller 140 interfaces with ARM processor 104 using internal bus 138. The memory controller 140 also communicates with the external bus interface (EBI) 146. Memory controller 140 is also in communication with static random access memory (SRAM) 148, and flash memory 150. Flash memory 150 is in communication with flash programmer 154. The memory controller 144 is also in communication with peripheral data controller 152. Additional application specific logic 156 communicates with the internal bus 138 and may also have external connections. A second PIO 158 provides communication with an Ethernet medium access control (MAC) 160. The second PIO 158 also communicates with a universal asynchronous receiver/transmitter 162, a serial peripheral interface (SPI) 164, a two wire interface 166, and an analog to digital converter 168. These devices and interfaces connect through internal bus 138 with a controller area network bus (CAN) 170, a universal serial bus (USB) devices 172, a pulse width modulator (PWM) controller 174, a synchro serial controller 176, and a timer/counter 178. These devices, CAN 170, USB device 172, PWM controller 174, synchro serial controller 176 and timer/counter 178 interface with third PIO 180, which provides external input and output. While these elements are typical of many SoCs, other devices may be incorporated, and some may not be included.

FIG. 2 is a block diagram of a dynamically configurable shared scan clock channel architecture in accordance with embodiments described herein. The architecture 200 includes multiple hard macros 202, 204, and 206. The hard macros 202, 204, and 206 may be memories that provide specific dedicated functions, with each hard macro embodying a particular function. Each hard macro 202, 204, and 206 communicates with programmable scan configuration block (PSCB) 210 during the testing process. The PSCB 210 allows re-use of unused clock channels. These unused clock channels may be used to design hard macro scans, and may be designed to scan particular functions or operations performed by the hard macro being tested. PSCB 210 incorporates an N to 2^{N} decoder 212. The N to 2^{N} decoder 210 receiver input from an N-bit Joint Test Action Group (JTAG) data register (JDR) 208. JTAG is a test standardization group that promulgates test standards and test device standardization. The N-Bit JDR 208 incorporates JTAG data register control bits that hold a static value in test mode. The JDR 208 is programmed through a JTAG interface. PSCB 210 also incorporates smart XOR 214. Smart XOR 214 provides for dynamic configuration of the shared scan-clock channel architecture 200, as described in further detail below. PSCB 210 provides scan out data to input/output device 216 (IO). IO 216 provides both clock and scan out data. IO 216 forwards scan clock information and scan in information to PSCB 210.

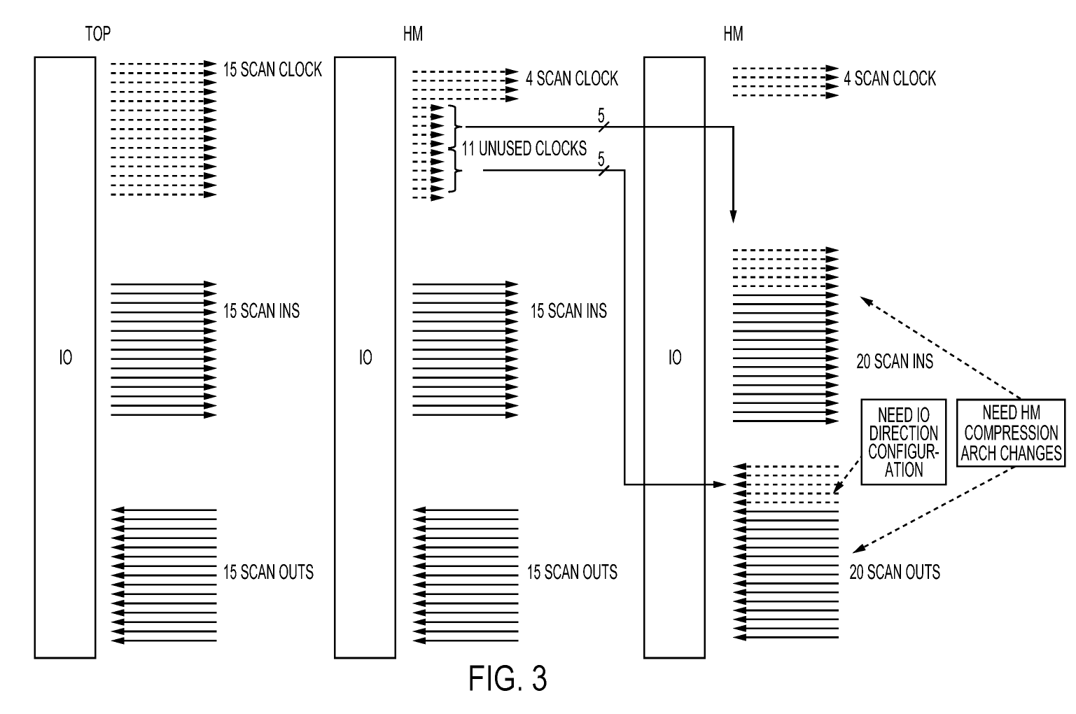

FIG. 3 shows the differences in clock utilization between existing scan clock channel architectures and the dynamically configurable scan clock architecture described herein. The fifteen scan clocks shown at the left in FIG. 3 are provided for testing hard macros are provided by IO 216. Of these fifteen scan clocks only four are used by the hard macros in the existing architecture, leaving eleven unused clocks. In the dynamically configurable scan clock architecture of the disclosure, the eleven unused clocks are apportioned are shown in FIG. 3. IO 210 provides five of the unused clocks to the fifteen scan ins provided by the existing architecture. The result is twenty scan ins available for use. Five additional unused clocks are also provided for the scan outs to IO 210. It should be noted that both sets of the five re-allocated unused clocks require hard macro compression architecture changes. The five unused cocks allocated to the scan out operation required IO direction configuration changes to allow them to be used to scan out scan test results5.

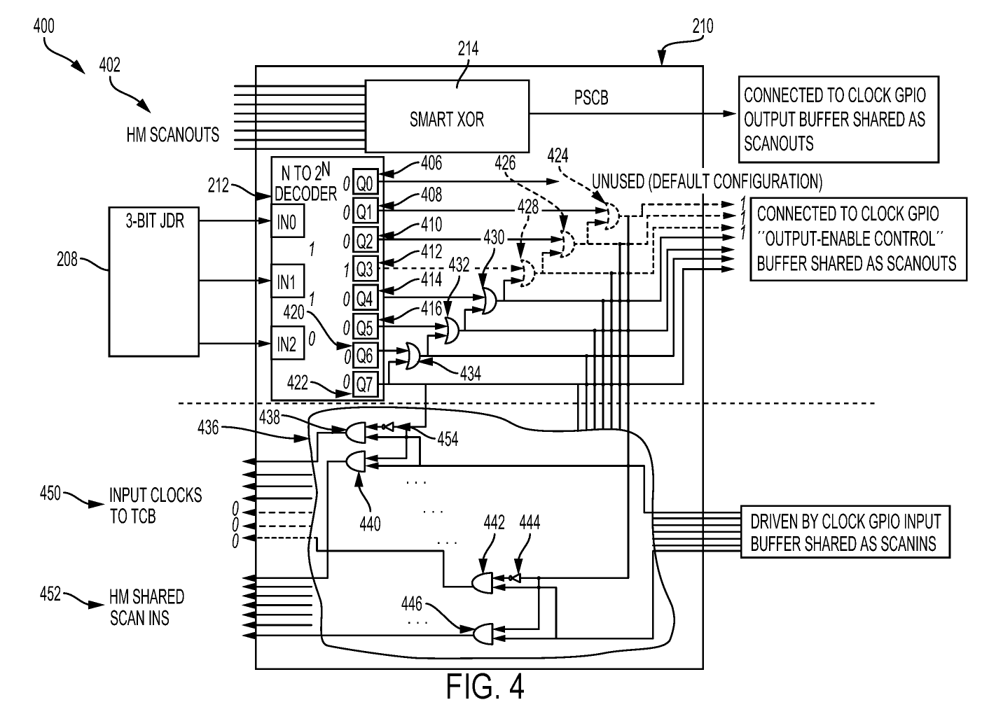

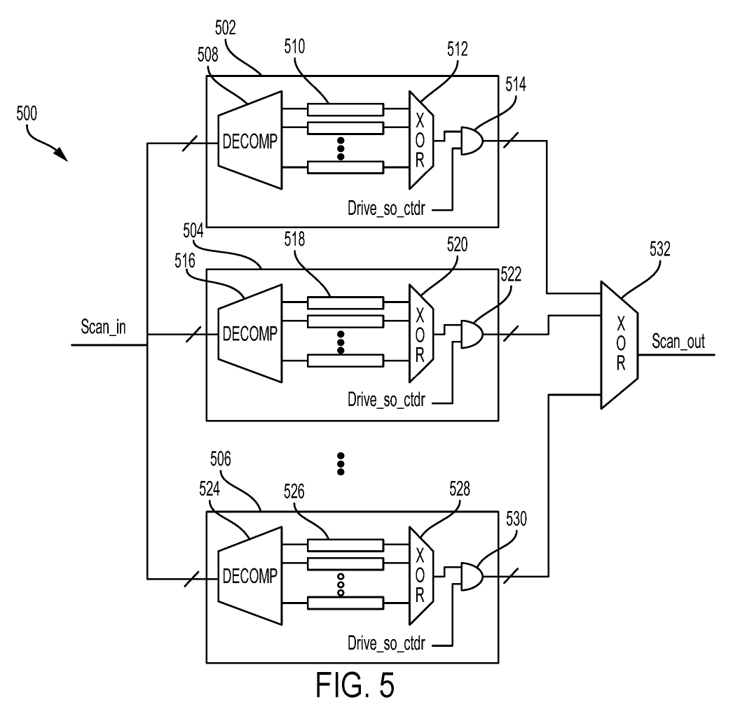

FIG. 4 is a block diagram of the PSCB 210. PSCB assembly 400 receives the hard macro scan outs 402 from all of the hard macros to be tested. These are input to the PSCB assembly 400 and are sent to the smart XOR 214, which will be discussed in more detail below, in FIG. 5. The outputs from the smart XOR 214 are connected to the clock general purpose input/output (GPIO) output buffer so that the scan outs may be shared as scan out values. A three-bit JDDR 208 supplies at least one address to N to 2^{N} decoder 212, located within the PSCB 210. While only one address may be provided based on the testing needs, the three-bit JDR 208 is typical and provides three addresses which are input to N to 2^{N} decoder 212. These inputs aid in determining which outputs go to a logic high value, and ultimately which testing channels may be reallocated. As illustrated in FIG. 4, these inputs may be in the following logic states: 1, 1, and 0. After decoding at N to 2^{N} decoder 212 the outputs are as illustrated. Output Q0 406 is in a logic low or 0 state. This output is the default configuration and is unused. Output Q1 408 is also in a logic low state, and is passed to OR gate 424 as one of two inputs to the gate. Similarly, output Q2 410 is in a logic low or 0 state with the decoder output passing to OR gate 426. Output Q3 412 is output as a logic high or 1 state with the decoder output passing to OR gate 428. Output Q4 414 is output as a logic low or 0 state with the decoder output passing to OR gate 430. Output Q5 416 is output as a logic low or 0 state with the output passing to OR gate 432. Output Q6 420 is output as a logic low or 0 state with the output passing to OR gate 434. OR gates 424 through 434 are cascaded together with each gate receiving input from an adjacent gate. OR gate 434 receives input from decoder outputs Q6 420 and Q7 422. Test control block 436, discussed in greater detail below, is also ties to each OR gate 424 through 436 output line within PSCB 210. OR gate 434 receives the output from decoder outputs Q7 and Q6, OR gate 432 receives as inputs the output from OR gate 434 and decoder output Q6. OR gate 430 receives as inputs the output from OR gate 434 and decoder output Q5. OR gate 428 receives as inputs the output from OR gate 432 and decoder output Q4. OR gate 426 receives as inputs the output from OR gate 430 and decoder output Q2. OR gate 424 receives as inputs the output from OR gate 426 and decoder output Q1.

Each output from an OR gate described above is also tied to an input into test control block 436. Test control block 436 receives the input clocks 450 and the hard macro shared scan ins 452. Within test control block 436 AND gates 438, 440 442, and 446 act as switches. In the case of AND gates 438 and 442 and inverter or NOT gate is used to switch the data line to one of the outputs. For AND gate 430 inverter 454 switches the data line, and for AND gate 442 inverter 444 provides the switching function. Test control block 436 is driven by the clock GPIO input buffer which is shared as scan ins. Test control block 436 provides outputs to the output of OR gates 424-434. After this process the output is a logic high state for decoder outputs Q1, Q2, and Q3. These logic values of 1 are driven low by the inverters within the test control block 436. The action of the PSCB 210 is to re-allocate unused clocks as needed based on the information input to the three-bit JDR 208.

FIG. 5 illustrates a block diagram of the smart XOR that is included in the PSCB 210 of FIG. 4. The assembly 500 includes representative blocks 502, 504, and 506 which are the blocks of a SoC that are tested using the methods described herein. Block 502 includes decompressor 508, which is linked to multiple channels 510. These multiple channels 510 are also linked to XOR gate 512, with eighteen channels output. XOR gate 512 provides input to AND gate 514. AND gate 514 may also receive input such as the drive_so_ctdr input shown. Block 504 is structured similarly with decompressor 516, twenty-one channels 518, XOR gate 520 and AND gate 522. Block 506 includes decompressor 524, fifteen channels 526, XOR gate 528, and AND gate 530. Blocks 502, 504, and 506 all input to smart XOR 532. The smart XOR 532 always provides the maximum possible number of possible output channels. When a block provides less than the maximum number of possible channels, such as blocks 502 and 506 shown in FIG. 5, the smart XOR 532 receives the lower number of channels and holds all other channels to zero so as to maintain a maximum of twenty-one channels output.

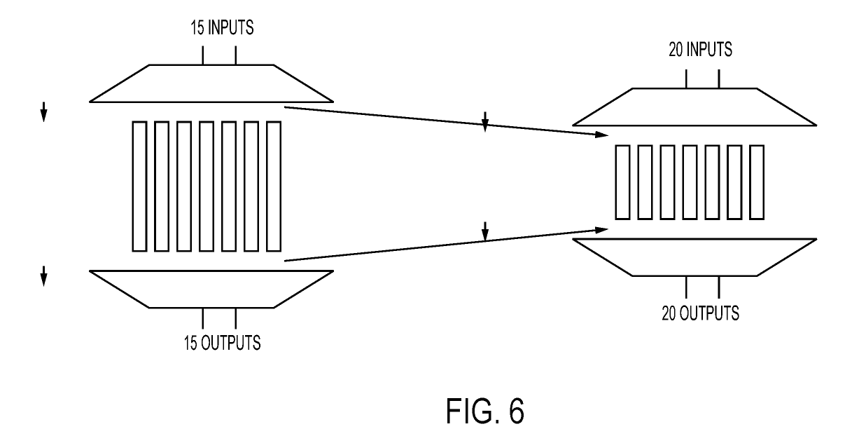

FIG. 6 depicts the reduction in test time through the use of the methods and apparatus described herein. Larger core devices, such as SoCs, are compression limited in testing, not chain tree length limited. The compression factor (CF) is a function of the number of scan channels, as shown by the equations below:

CF=(no. of flops)/(chain length*no. of external scan channels)

Chain length=(no. of flops)/(compression*no. of external scan channels) With an increase in the number of available external channels, as is depicted in FIG. 6, the internal chain length reduces for a given targeted compression factor. Test time is computed using the equation below:

Test time=chain length*no. of patterns.

This is shown in FIG. 6 where in the test set-up shown on the left 15 test inputs are provided. If the number of chain tree length channels can be increased, then the test time is reduced, as shown in the test set-up shown on the right where 20 test inputs are provided and the test time, depicted as channel a vertical length in the figure is reduced.

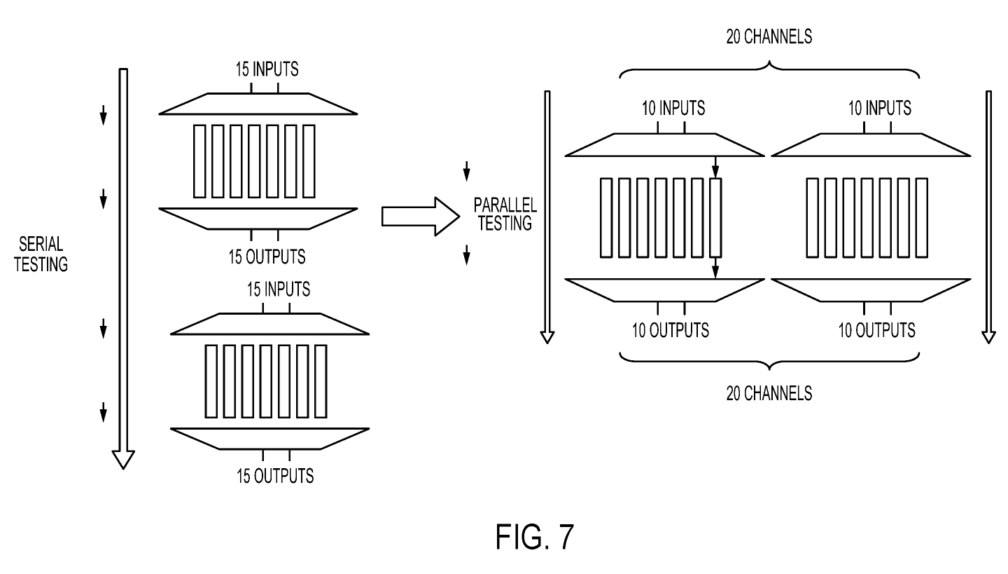

FIG. 7 illustrates that test time reductions are also achievable when testing scan channels in parallel. Parallel testing is useful in testing smaller cores on electronic devices as these cores are not compression limited, but are chain tree length limited. For smaller cores increasing the number of channels available does not aid in reducing test time. In FIG. 7 at the left of the figure two groups of fifteen channels are shown being testing serially, for a total of thirty channels tested. Testing twenty of the thirty channels in two groups of ten channels each enables effective parallel core testing. The core grouping or selection may be changed if there is any power increase or affect when the device is fabricated in silicon.

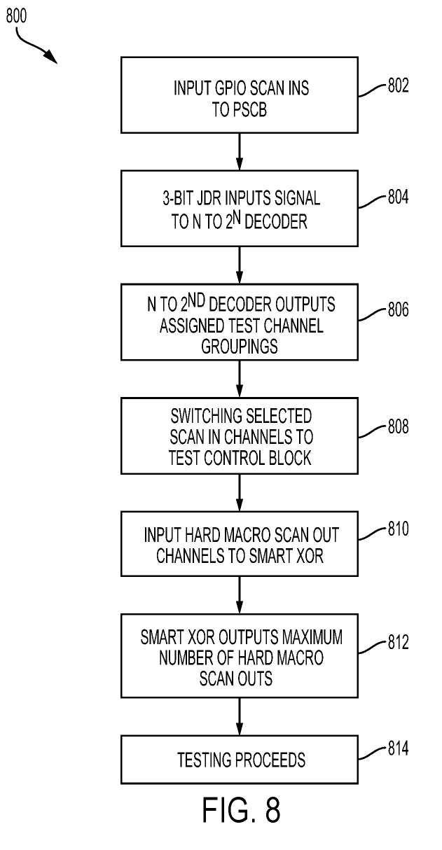

FIG. 8 is a flowchart of a method of testing an electronic device having multiple cores, such as a SoC. In the method 800, in block 802 the GPIO inputs scan in information to the PSCB. In block 804 the three-bit JDR inputs a three-bit signal to the N to 2^{N} decoder. The N to 2^{N} decoder outputs assigned test channel groupings in block 806. The selected scan in channels are them switched to the test control block in block 808. In step 810 the hard macro scan out channels are output to the smart XOR which fills in the maximum number of test channels per block 812. In block 814 testing proceeds.

It is understood that the specific order or hierarchy of blocks in the processes disclosed is an illustration of exemplary approaches. Based upon design preferences, it is understood that the specific order or hierarchy of blocks in the processes may be rearranged. The accompanying method claims present elements of the various blocks in a sample order, and are not meant to be limited to the specific order or hierarchy presented.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but is to be accorded the full scope consistent with the language claims, wherein reference to an element in the singular is not intended to mean “one and only one” unless specifically so stated, but rather “one or more.” Unless specifically stated otherwise, the term “some” refers to one or more. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed as a means plus function unless the element is expressly recited using the phrase “means for.”

It is to be understood that the claims are not limited to the precise configuration and components illustrated above. Various modifications, changes and variations may be made in the arrangement, operation and details of the systems, methods, and apparatus described herein without departing from the scope of the claims.

What is claimed is:

1. A method for testing an electronic device, comprising:
inputting at least one scan for scan configuring;
inputting a signal having a predetermined number of bits to a decoder;
outputting at least one assigned test channel based on the output of the decoder;
switching at least one selected scan in channel to a test control block;
inputting hard macro scan out channels to a channel maximization device; and
testing the electronic device.

2. The method of claim 1, wherein the predetermined number of bits is input by a data register.

3. The method of claim 1, wherein the switching at least one selected scan in channel is selected to maximize a number of channels input for testing.

4. The method of claim 1, wherein inputting hard macro scan out channels is used to maximize a number of channels for testing.

5. The method of claim 1, wherein the hard macro scan out channels are grouped to maximize testing in serial.

6. The method of claim 1, wherein the hard macro scan out channels are grouped to maximize testing in parallel.

7. An apparatus for dynamically configuring shared scan clock channels, comprising:
a programmable scan configuration block; and
a predetermined bit register in communication with the programmable scan configuration block.

8. The apparatus of claim 7, wherein the programmable scan configuration block further comprises:
a plurality of clock inputs;
a plurality of scan inputs; and
a plurality of scan outputs; wherein the programmable scan configuration block is configured to reallocate at least a portion of the plurality of clock inputs to other inputs and outputs of the programmable configuration block.

9. The apparatus of claim 8, wherein the reallocation is based on a value stored in the predetermined bit register.

10. The apparatus of claim 8, wherein the other inputs and outputs comprise the plurality of scan inputs and the plurality of scan outputs.

11. The apparatus of claim 7, wherein the programmable scan configuration block incorporates a decoder and a smart exclusive OR gate.

12. The apparatus of claim 8, wherein the programmable scan configuration block cascades logic gates to output enable a control buffer.

13. The apparatus of claim 9, wherein the cascaded logic gates comprise AND gates.

14. The apparatus of claim 7, wherein the programmable scan configuration block incorporates a smart logic gate in communication with a general purpose input output buffer.

15. The apparatus of claim 11, wherein the smart logic gate is an exclusive OR gate.

16. An apparatus for dynamically configuring shared scan clock channels, comprising:
means for inputting at least one scan for scan configuring;
means for inputting a signal having a predetermined number of bits to a decoder;
means for outputting at least one assigned test channel based on the output of the decoder;
means for switching at least one selected scan in channel to a test control block;
means for inputting hard macro scan out channels to a channel maximization device; and
means for testing the electronic device.

17. The apparatus of claim 16, further comprising means for switching at least one selected scan in channel.

18. The apparatus of claim 16, wherein the means for inputting hard macro scan out channels maximizes a number of channels for testing.

19. The apparatus of claim 16, wherein the means for inputting hard macro scan out channels maximizes a number of channels for serial testing.

20. The apparatus of claim 16, wherein the means for inputting hard macro scan out channels maximizes a number of channels for parallel testing.
